(19) United States
(12) Patent Application Publication
(10) Pub. No.: US 2015/0162369 A1
(43) Pub. Date: Jun. 11, 2015

(54) Single-Poly Floating Gate Solid State Direct Radiation Sensor Using STI Dielectric And Isolated PWells

(71) Applicant: Tower Semiconductor Ltd., Migdal Haemek (IL)

(72) Inventors: Yakov Roizin, Afula (IL); Evgeny Pikhay, Haifa (IL); Vladislav Dayan, Nazareth lIIit (IL); Micha Gutman, Haifa (IL)

(73) Assignee: Tower Semiconductor Ltd., Migdal Haemek (IL)

(21) Appl. No.: 14/101,282

(22) Filed: Dec. 9, 2013

(51) Int. Cl. H01L 27/146

(52) U.S. Cl. CPC H01L 27/14614

(57) ABSTRACT

Solid state radiation sensors include a floating gate (FG) structure having a large control capacitor region disposed on thick dielectric portion over a control gate (CG) implemented by an isolated P-well region, and a tunneling capacitor region disposed on thin gate oxide dielectric over another tunneling gate (TG) isolated P-well region. Opposite voltages (e.g., +5V/−5V) are respectively applied to the CG and TG P-well regions to charge the FG structure by Fowler-Nordheim tunneling. During exposure, radiation striking the sensor discharges the FG structure by generating electron-hole pairs in the dielectric portion separating the CG P-well region and the control capacitor region. After exposure, the total ionizing dose (TID) is calculated, e.g., by measuring the threshold voltage shift of a CMOS readout inverter controlled by the residual charge stored on the FG structure. Sensor performance is enhanced by metal plates, utilizing two control capacitors, or modifying the FG electrode layout.

### FIELD OF THE INVENTION

This invention relates to radiation sensor systems, and particularly to low-power solid state direct radiation sensors used, for example, in dosimeters.

### BACKGROUND OF THE INVENTION

Conventional floating gate type radiation sensors are utilized for many purposes, and typically include a polycrystalline silicon floating gate disposed next to an oxide layer. The floating gate is typically pre-charged before exposure (irradiation). During exposure, electron hole pairs are generated in the oxide layer that discharge the floating gate. The residual charge stored on the floating gate is then measured to determine the amount of radiation received during the exposure period.

The radiation sensing method described in U.S. Pat. No. 4,788,581 is based on charging of the floating gate by e-h pairs produced during radiation exposure. This approach requires applying voltage in course of sensing, which is problematic for applications which require ultra-low power operation (e.g., REID systems). In addition, the described sensor utilizes relatively thin oxide for converting the radiation into e-h pairs (which leads to low sensitivity).

U.S. Pat. No. 5,596,199 discloses another radiation sensor based on the discharge of an array of commercial EEPROM devices by radiation, and relies on mathematical analysis of array performance to determine the amount of received radiation. No development of radiation sensing device was performed to enhance the cell sensitivity, thus low sensitivity and precision is expected using this approach.

U.S. Pat. No. 6,172,368 discloses another radiation sensor that requires a complex dual-gate manufacturing process, and exhibits limited sensitivity (40 mV/Gy) due to the use of relatively thin oxide for converting the radiation into e-h pairs.

US Patent Application 20100096556 is based on discharge of field oxide capacitor, coupled to injector and read-out transistor. It features better sensitivity then previous approaches due to utilization of thick field oxide for converting the radiation into e-h pairs. However, the sensor has no control gate, thus leading to poor controllability of the sensor during operation (e.g., control over the amount of injected charge, sensor sensitivity during exposure, and read-out operations).

What is needed is a solid state direct radiation sensor that exhibits high sensitivity to ionizing radiation and excellent programming and readout controllability. What is also needed is for the solid state direct radiation sensor to be producible using standard semiconductor fabrication processes (e.g., a standard “single-poly” CMOS fabrication process/flow) with zero or minimal modifications.

### SUMMARY OF THE INVENTION

The present invention is directed to a solid state direct radiation sensing device, consisting of a single sensor or including an array of radiation sensors that are fabricated on a semiconductor (e.g., silicon) substrate, where each sensor includes a control gate formed by an isolated (first) P-well region that is disposed under a thick dielectric structure (e.g., a shallow trench isolation (STI) portion or a field oxide (FOX) region), and under a control capacitor region of a polycrystalline silicon floating gate (FG) structure. The dielectric structure facilitates high sensitivity to ionizing radiation by providing a thick sensing volume that increases the number of electron-hole pairs participating in FG discharge during exposure. In addition, the stacked arrangement formed by the FG control capacitor region, the dielectric structure and the isolated P-well region forms a superior control capacitor that facilitates excellent programming controllability, and is achievable using standard (e.g., “single-poly” CMOS) fabrication process flows, thereby facilitating the cost-effective production of solid state direct radiation sensors and detecting/processing circuitry on the same silicon substrate.

In one embodiment of the present invention, each sensor further includes a tunneling capacitor formed by capacitive coupling between a tunneling capacitor region of the FG structure and an underlying isolated (second) P-well region, where the tunneling capacitor region and the underlying P-well region are separated by a relatively thin intervening gate oxide portion and control capacitor is separated by a relatively thick oxide portion (i.e., a thickness of the dielectric under the control gate portion of the FG is at least ten times the thickness of the thin gate oxide portion, and when STI dielectric is used, the dielectric thickness is approximately fifty times that of the gate oxide). In a specific embodiment, both isolated P-well regions are entirely contained within an N-well (e.g., disposed over a deep N-well region and surrounded by peripheral “shallow” N-well regions), and both the isolated P-well and N-well regions are coupled by suitable contact structures and associated conductors to appropriate programming or bias voltage sources. In a particular embodiment, the various structures forming the control gate and the tunneling gate are sized such that a first capacitance of the control capacitor is in the range of five to one-hundred times greater than a second capacitance of the tunneling capacitor to provide the sensor with excellent programming controllability, and to facilitate programming of the FG structure using Fowler-Nordheim tunneling techniques.

According to another aspect of the present invention, each sensor includes a readout circuit fabricated on the substrate adjacent to the control and tunneling capacitor structures. The readout circuit includes at least one field-effect-type “read-out” transistor having source/drain diffusions formed in the substrate and a gate structure formed by a readout region of the FG structure (i.e., such that current through the readout transistor is proportional to the charge stored on the FG structure). In one specific embodiment, the readout circuit is a CMOS inverter including both a PMOS transistor and an NMOS transistor having gate structures formed by associated (third and fourth) readout regions of the contiguous FG structure, and the residual charge stored on FG structure (i.e., during or after exposure) is estimated by measuring a shift in the inverter's voltage transfer curve caused by exposure.

According to another embodiment of the present invention, the solid state direct radiation sensing device also includes a control circuit fabricated on the same substrate as the array of sensors and using the same standard (e.g., CMOS) fabrication techniques used to produce the sensors. During a pre-exposure programming (charging) period in which an initial charge is stored on the FG structure, the control circuit applies opposite programming voltages on the control gate and the tunneling gate of each sensor (e.g., −5V on the control gate, and +5V on the tunneling gate, or vice versa), whereby the large capacitive difference between the control and tunneling capacitors causes most of the voltage to fall on the tunneling capacitor, thereby causing Fowler-Nordheim tunneling of electrons or holes (according to polarity of applied voltages) from the (second) isolated P-well region through the tunneling gate oxide portion to the tunneling capacitor region of the FG structure. During subsequent exposure, the control circuit is configured to apply optional biasing voltages on the control gates of each sensor while the initial charge is removed from the FG structure in proportion to an amount of received ionizing radiation (i.e., due to electron/hole separation in the STI dielectric structure). During post-exposure readout period, the control circuit estimates the dose of absorbed radiation using signals generated by the readout readout circuit of each sensor, for example, by measuring the amount of current passing through the one or more readout transistors. In a presently preferred embodiment, the readout circuit is formed as a CMOS inverter including readout (first) PMOS and NMOS transistors that are controlled by narrow readout regions of the FG structure, and transfer (second) PMOS and NMOS transistors that are controlled by wordline voltages, whereby the dose estimate is performed by determining the change in the Vin-Vout curve of the CMOS inverter that occurred during exposure.

Various alternative embodiments include additional features that are optionally employed to achieve improved sensor performance.

According to a first alternative embodiment, an additional (second) dielectric layer is formed over the FG structure, and a patterned metal plate disposed on the additional dielectric layer and positioned over the control capacitor region of the FG structure, wherein the patterned metal plate and the (first) isolated P-well are electrically connected, for example, by way of metallization wiring, thereby forming a two-part control gate. This arrangement also forms two substantially equal control capacitors including a lower (first) capacitor formed by the isolated P-well, the STI dielectric structure and the FG control capacitor region, and an upper (second) capacitor formed by the patterned metal plate, the additional dielectric layer and the FG control capacitor region. This approach facilitates reducing the chip area occupied by each sensor by almost half while achieving the same total control capacitance.

According to a second alternative embodiment, each sensor includes two separate (first and second) FG structures having respective comb-like control capacitor regions disposed on the STI dielectric portion and over the first isolated P-well region in an interdigitated arrangement (i.e., such that parallel fingers extending from a base portion of the first comb-like control capacitor region extend between associated pairs of fingers of the second comb-like control capacitor region). Each sensor includes two (first and second) tunneling gates respectively disposed over associated isolated P-well regions, and the two floating gate structures include respective tunneling capacitor regions disposed over an associated isolated P-well region. During a first phase of the pre-exposure programming period, a positive voltage (e.g., +5V) is applied both to the control gate and to the tunneling gate that is coupled to the second FG structure, and a negative voltage (e.g., −5V) is applied to the tunneling gate coupled to the first FG structure, whereby Fowler-Nordheim tunneling of electrons generates a net-negative charge on the first FG structure. During a second phase of the pre-exposure programming period, a negative voltage (e.g., −5V) is applied to both the control gate and to the tunneling gate coupled to the first FG structure, and a positive voltage (e.g., +5V) is applied to the tunneling gate coupled to the second FG structure, whereby Fowler-Nordheim tunneling of holes generates a net-positive charge on the second FG structure. Pre-charging the two FG structures in this manner produces an enhanced electric field separating the different (net-positive and net-negative) charges during ionization, which in turn leads to decreased recombination (i.e., more electrons/holes reach the two FG structures to discharge the respective stored charges).

The sensor device embodiments described above are characterized by passive exposure operations (i.e., none of the sensors consume electric power during exposure to radiation, and power is only consumed during the programming/charging and read-out processes). Although passive exposure is highly desirable for certain mobile applications because it minimizes power consumption, it may produce undesirably low radiation detection (i.e., low sensor sensitivity) in the sensor structures described above due to high electron/hole recombination in the thick STI dielectric. Moreover, while applying a biasing voltage to FG structure during exposure (i.e., by way of the control gate) one can increase the resulting electric field in the STI dielectric, which would suppress electron/hole recombination, this approach may produce undesirable charge loss from the FG structure due to leakage through the thin tunneling gate dielectric between the P-well/tunneling gate and the FG tunneling capacitor region. To address this issue, according to a fourth alternative embodiment of the present invention, each sensor includes two control gates that are controlled to apply opposite biasing voltages on the floating gate during the exposure period. In a first specific embodiment, the floating gate structure is patterned to include two control capacitor region portions respectively disposed over two separate (first and third) isolated P-well regions, whereby two equal control capacitors are respectively formed by the first control gate (i.e., the (first) isolated P-well region) and the first control capacitor region portion, and by the second control gate (implemented by the separate (third) isolated P-well region below the second control capacitor region portion. In a second specific embodiment, the first control gate is implemented by the first isolated P-well region disposed below a single control capacitor region, an additional (second) dielectric layer is formed over the floating gate structure, and the second control gate is implemented by a metal plate disposed on the additional dielectric layer and positioned over the control capacitor region. By separating the control capacitor into two identical capacitor portions, and by applying opposite (e.g., positive/negative) biasing voltages to the two control gates, the desired enhanced electric field is generated in the STI dielectric by one of the two capacitor portions, whereby sensor sensitivity is increased, while tunneling through the thin gate oxide is not induced in the tunnel capacitor portion, thereby avoiding undesirable charge loss (i.e., the charge stored on the FG structure is not influenced by the applied bias voltage).

According to an exemplary practical embodiment of the present invention, a solid state direct radiation sensing device includes an array of sensors having a tunneling gate and a readout circuit disposed at opposite ends of the FG control capacitor region, and the sensors are disposed in multiple rows and arranged in an alternating “flipped” pattern such that all of the tunneling gates of two adjacent rows are disposed in a first (horizontal) space disposed between the two adjacent rows, with the readout circuits being positioned between second and third (horizontal) spaces above and below the two adjacent rows. This arrangement further facilitates forming solid state direct radiation sensing devices including arrays of radiation sensors and associated digital detecting/processing circuitry on the same silicon substrate by enabling random access for pre-charging and reading (i.e., by way of bitlines and wordlines disposed along the spaces between associated rows and columns of sensors).

According to another exemplary practical embodiment of the present invention, each sensor is fabricated using a single-poly nano-scale (e.g., 0.18 μm) CMOS fabrication process such that a width of each FG readout gate region is in the range of 22 nm and 1 μm, and such that each FG control capacitor region has a width and a length in a range of 1 μm and 1000 μm. Sensitivity of CMOS devices to ionizing radiation (total ionization dose-TID) strongly decreases in nano-scaled CMOS, so nano-scale (e.g., sub-micron) CMOS devices are less sensitive to ionizing radiation than larger CMOS devices. By forming the various sensors of the present invention with readout circuits having thin gate oxide with thicknesses below 10 nm provides radiation sensors with reduced risk of malfunction due to ionizing radiation. At the same time, utilization of FG discharging principles enables creation of high sensitivity radiation silicon sensors, so constructing the various sensors of the present invention with FG control capacitor regions with a width and length in the range of 1 μm and 1000 μm provides radiation sensors with excellent sensitivity. Combining these two concepts (i.e., floating gate-based radiation sensors with small CMOS readout transistors and large control capacitors) produces a unique combination of analog electronic designs that include sensors and control (detecting/processing) circuitry on the same silicon substrate. Moreover, because the sensors are small and ultra-low power consuming (i.e., below 1 μW, defined by the driver/readout circuitry), sensor devices formed in accordance with the present invention are suitable for a variety of challenging applications, in particular, in systems employing radiation for sterilization, radiation safety and security devices, in-vivo dosimeters for precise dose delivery control in radiation therapy and other medical devices. Application of embedded radiation sensors also facilitates the production of CMOS chips with enhanced radiation hardness (i.e., on-the-chip sensors allow introducing correction that accounts for absorbed dose).

### BRIEF DESCRIPTION OF THE DRAWINGS

These and other features, aspects and advantages of the present invention will become better understood with regard to the following description, appended claims, and accompanying drawings, where:

FIG. 1 is a cross-sectional side view showing a portion of a solid state direct radiation sensing device according to an embodiment of the present invention;

FIG. 2 is a simplified cross-sectional side view showing the sensor device of FIG. 1 in additional detail;

FIGS. 2A, 2B and 2C are simplified cross-sectional side views showing the sensor device of FIG. 2 during programming, exposure and readout operating periods, respectively;

FIG. 3 is a simplified cross-sectional side view showing a sensor including a CMOS inverter readout circuit according to an alternative embodiment of the present invention;

FIG. 4 is a simplified cross-sectional side view showing another sensor including a CMOS inverter readout circuit according to another alternative embodiment of the present invention;

FIG. 5 is a simplified cross-sectional side view showing a sensor including a two-part control gate according to another alternative embodiment of the present invention;

FIG. 6 is a top plan view showing a sensor including two comb-shaped, interdigitated floating gate structures according to another alternative embodiment of the present invention;

FIG. 7 is a simplified cross-sectional side view showing a portion of a sensor device including a sensor similar to that shown in FIG. 6;

FIG. 8 is a simplified cross-sectional side view showing a sensor including two control gates according to another alternative embodiment of the present invention;

FIG. 9 is a simplified cross-sectional side view showing a sensor including two control gates according to another alternative embodiment of the present invention;

FIG. 10 is a top plan view showing a sensor device including an array of the sensors according to a simplified exemplary practical embodiment of the present invention;

FIG. 11 is a top plan view showing a sensor utilized in the array of FIG. 11 according to the exemplary practical embodiment of the present invention; and

FIG. 12 is a perspective top view showing a simplified CMOS circuit constructed in accordance with another embodiment of the present invention.

### DETAILED DESCRIPTION OF THE DRAWINGS

The present invention relates to an improvement in FG-type radiation sensors. The following description is presented to enable one of ordinary skill in the art to make and use the invention as provided in the context of a particular application and its requirements. As used herein, directional terms such as “upper”, “above”, “over”, “lower”, and “below” are intended to provide relative positions for purposes of description, and are not intended to designate an absolute frame of reference. The terms “coupled” and “connected”, which are utilized herein, are defined as follows. The term “connected” is used to describe a direct connection between two circuit elements, for example, by way of a metal line formed in accordance with normal integrated circuit fabrication techniques. In contrast, the term “coupled” is used to describe either a direct connection, capacitive coupling, or an indirect connection between two circuit elements. For example, two coupled elements may be directly connected by way of a metal line, or indirectly connected by way of capactive coupling or by way of an intervening circuit element (e.g., a capacitor, resistor, inductor, or by way of the source/drain terminals of a transistor). Various modifications to the preferred embodiment will be apparent to those with skill in the art, and the general principles defined herein may be applied to other embodiments. Therefore, the present invention is not intended to be limited to the particular embodiments shown and described, but is to be accorded the widest scope consistent with the principles and novel features herein disclosed.

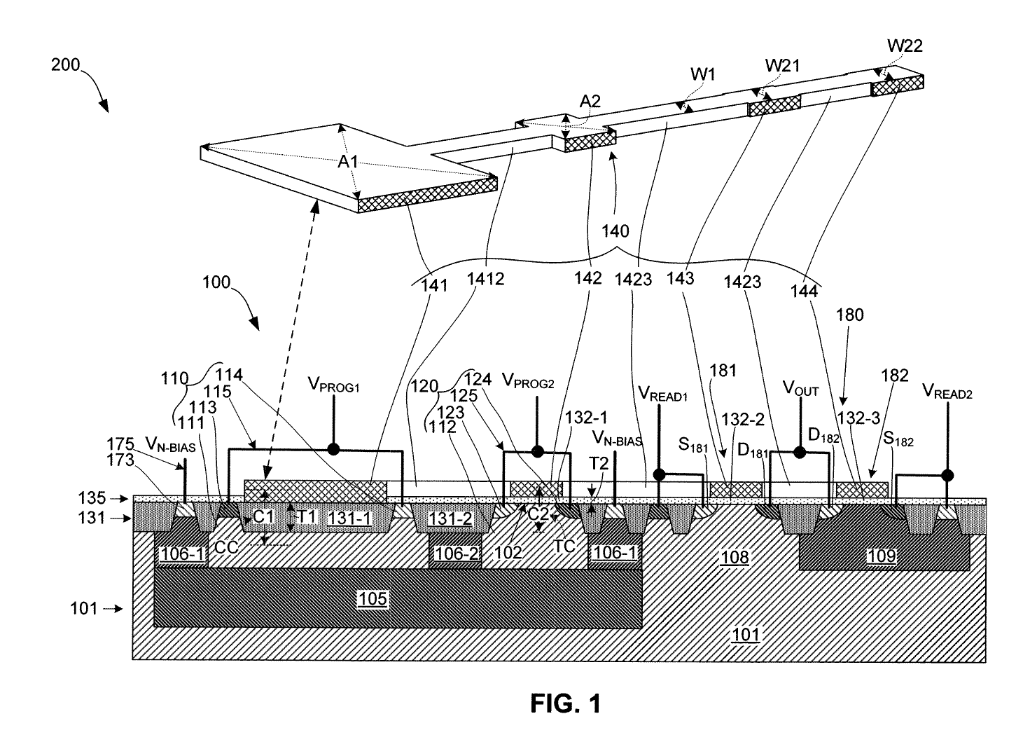

FIG. 1 is a partial cross-sectional view showing a solid state direct radiation sensing device 200 including a radiation sensor 100 that is fabricated on a semiconductor (e.g., silicon) substrate 101 in accordance with an exemplary embodiment of the present invention. Although only one sensor element is shown, it is understood that radiation sensing device 200 includes multiple sensors 100 disposed in an array.

According to an aspect of the invention, sensor 100 generally includes a control gate 110, a tunneling gate 120, a floating gate (FG) structure 140, and a readout circuit 180 that are fabricated on substrate 101 using known semiconductor processing techniques. In one embodiment, sensor 100 is entirely formed using a standard single-poly CMOS fabrication process.

Referring to the left side of FIG. 1, according to a first aspect of the present invention, control gate 110 is implemented by an isolated P-well region 111 formed by a P-type dopant that is diffused into substrate 101 using know techniques. In the exemplary embodiment, isolated P-well region 111 is entirely disposed over a deep N-well region 105 formed in the substrate 101, and surrounded by “shallow” N-well regions 106-1 that extend from surface 102 to deep N-well region 105. In other embodiments, isolated P-well region 111 may be isolated using other N-doped region types (e.g., formed in an N-doped substrate). In an alternative embodiment, sensor 100 is implemented using isolated N-well regions disposed inside P-well regions (e.g., formed in an N-doped substrate). In either case, the use of isolated well region 111 (i.e., either an isolated N-well or an isolated P-well) to implement control gate 110 facilitates both low-cost and reliable fabrication, and also provides superior operating characteristics.

As also indicated in FIG. 1, control gate 110 also includes a P+ contact region 113 disposed adjacent an upper surface 102 of substrate 101 and contacting a first (left) end region of isolated P-well region 111, an N+ contact region 114 disposed adjacent upper surface 102 and contacting a second (right) end region of isolated P-well region 111, and metal signal lines 115 that transmit a programming voltage V_{PROG1} to isolated P-well region 111 by way of suitable contact structures (e.g., contact regions 113 and 114). Metal signal lines described herein (such as lines 115) are depicted in simplified form for clarity, and are understood to be implemented by standard metallization processing.

According to standard CMOS fabrication techniques, multiple discrete shallow trench isolation (STI) structures, generally indicated by reference number 131, are formed on substrate 101 to provide electrical isolation between adjacent doped regions and adjacent sensors. In the exemplary embodiment, one of these discrete STI dielectric structures, STI portion 131-1, forms a relatively large area dielectric structure that substantially entirely covers isolated P-well region 111. In one embodiment, STI portion 131-1 has a nominal thickness of 3500 A (Angstroms), which facilitates high sensitivity to ionizing radiation by providing a thick sensing volume that increases the amount of electron-hole pairs produced by radiation during exposure. Other STI structures (e.g., STI portion 131-2) serve the conventional function of isolating isolated P-well region 111 from adjacent doped regions.

Although control capacitor CC is presently preferably implemented using STI dielectric, other thick dielectric structures may also be used. For example, field oxide (FOX) formation is a typically included in standard CMOS fabrication flows, and therefore may be used in place of STI portion 131-1 without introducing modifications to the standard CMOS flow. Further, a field oxide structure fabricated using thermal oxidation may provide an advantage over STI by producing lower electron-hole recombination, and facilitates forming a thinner CG dielectric structure (e.g., a FOX dielectric structure thickness T1 can be approximately 20-30 times that of thickness T2). Alternatively, other dielectric types (e.g., special thick thermal oxides that are fabricated using a special mask) may utilized to reduce the thickness T1 of control capacitor dielectric portion 131-1 to approximately 500 A to 2000 A (i.e., approximately five to twenty times that of thickness T2), but the use of non-standard dielectric material would require a modification to the standard CMOS flow that could increase manufacturing costs. Accordingly, the appended claims are not limited to STI dielectric structures and the associated thickness provided below unless otherwise specified.

FG structure 140 is a contiguous, electrically conductive (e.g., strongly doped, silicided, or both) polycrystalline silicon structure 140 disposed over upper surface 102 and patterned using known techniques to include multiple regions 141 to 144 that are respectively connected by interconnecting regions 1412, 1423 and 1434, which serve to distribute the stored charge equally to all regions 141 to 144 of FG structure 140. As indicated by the perspective illustration at the top of FIG. 1, the largest region of FG structure 140 is control capacitor region 141. Control capacitor region 141 is disposed on (or over) STI dielectric portion 131-1 such that it capacitively coupled to isolated P-well region 111 and forms a control capacitor CC having a capacitance C1. As described in additional detail below, control capacitor CC facilitates excellent programming controllability, and is constructed using standard (e.g., “single-poly” CMOS) fabrication process techniques, which in turn facilitates the cost-effective production of both sensor 100 and control (detecting/processing) circuitry on silicon substrate 101 (i.e., by using the regions of FG structure 140, which are described in additional detail below).

Referring to the central portion of FIG. 1, sensor 100 further includes a tunneling capacitor TC formed by capacitive coupling between a tunneling capacitor region 142 of the FG structure 140 and a tunneling gate 120, which is implemented using a second (separate) isolated P-well region 112 formed in substrate 101 and separated from isolated P-well region 111 by “shallow” N-well region 106-2 and STI portion 131-2. Tunneling gate 120 also includes a P+ contact region 123 disposed adjacent an upper surface 102 of substrate 101 and contacting a first (left) end region of isolated P-well region 112, an N+ contact region 124 disposed adjacent upper surface 102 and contacting a second (right) end region of isolated P-well region 112, and metal signal lines 125 that transmit a programming voltage V_{PROG2} to isolated P-well region 112 by way of contact regions 123 and 124.

As with isolated P-well 111, isolated P-well region 112 is entirely contained within an N-well region formed by deep N-well 105 and peripheral N-well regions 106-1. Isolated P-well 112 is coupled by suitable contact structures (e.g., contact regions 123 and 124 and associated conductor 125) to appropriate programming or bias voltage sources. In a similar manner, the N-well region formed by deep N-well 105 and “shallow” N-well regions 106-1 and 106-2 is coupled by way of suitable contact structures (e.g., contact regions 173 and associated conductor 175) to an appropriate N-well bias voltage V_{N-BIAS}. Similar to isolated P-well 111, isolated P-well region 112 may be implemented using an isolated N-well.

To facilitate Fowler-Nordheim tunneling during programming, tunneling capacitor region 142 and underlying P-well region 112 are separated by a relatively thin (e.g., 15 nm or less) intervening tunneling (gate) oxide portion 132-1, which is formed by standard HV gate oxide utilized in the CMOS process flow to form NMOS transistors. In one embodiment, thickness T1 of the STI dielectric 131-1 is approximately fifty times greater than thickness T2 of tunneling (HV gate) oxide portion 132-1. As explained below, when suitable programming voltages V_{PROG1} and V_{PROG2} are applied to control gate 110 and tunneling gate 120, Fowler-Nordheim tunneling of holes (or electrons, depending on the applied voltages) occurs between substrate 101 and FG structure 140 through tunneling oxide portion 132-1.

In a particular embodiment, the various structures forming control capacitor CC and tunneling capacitor TC are sized such that a capacitance C1 of control capacitor CC is in the range of five to one-hundred times greater than a capacitance C2 of the tunneling capacitor TC. For example, as indicated by the perspective illustration at the top of FIG. 1, the desired ratio of C1 to C2 is achieved by forming control capacitor region 141 with an area A1 that is at least five times greater than A2*T1/T2 where A2 is the surface area of tunneling capacitor region 142. The desired C1/C2 ratio can be achieved by altering other device parameters (e.g., by utilizing a special dielectric deposition process to generate dielectric portion 131-1 with a thickness that achieves the desired ratio), but this approach may require undesirable modification of the standard CMOS fabrication process used to make sensor device 200. In a preferred embodiment, the C1 to 02 ratio is set such that Fowler-Nordheim tunneling is facilitated during a pre-exposure charging/programming period when opposite voltages are applied on isolated P-well regions 111 and 112 (e.g., when programming voltage V_{PROG1} supplied to control gate 110 is −5V (or +5V), and programming voltage V_{PROG2} supplied to tunneling gate 120 is +5V (or −5V)).

Referring to the right side of FIG. 1, sensor 100 further includes a readout circuit 180 that is fabricated simultaneously with sensor 100 and digital control circuitry (discussed below) on substrate 101 using a standard CMOS fabrication process. In the exemplary embodiment shown in FIG. 1, readout circuit 180 includes a NMOS field-effect-type readout transistor 181 controlled by a first readout region 143 of FG structure 140, and a PMOS field-effect-type readout transistor 182 controlled by a second readout region 144 of FG structure 140, although it is possible provide a readout circuit with just one of these two transistors. In particular, NMOS readout transistor 181 and PMOS readout transistor 182 are fabricated using the same specifications and process steps that are utilized in the standard CMOS fabrication flow to generate “normal” high voltage (HV) PMOS and NMOS devices. Specifically, NMOS readout transistor 181 includes a source region S₁₈₁ and a drain region D₁₈₁ formed in a P-type doped region 108 of substrate 101 in accordance with HV-NMOS specifications, with source region S₁₈₁ operably connected to receive a first read voltage V_{READ1}, and with drain region D₁₈₁ connected to provide an output voltage V_{OUT}, and with an HV gate oxide 132-2 having a thickness T2 of 10 nm disposed on substrate surface 102 over a channel region separating source region S₁₈₁ and drain region D₁₈₁. Similarly, PMOS readout transistor 182 includes a source region S₁₈₂ and a drain region D₁₈₂ formed in an N-well region 109 of substrate 101, with source region S₁₈₂ operably connected to receive a second read voltage V_{READ2}, with drain region D₁₈₂ connected to provide output voltage V_{OUT}, and with an HV gate oxide 132-3 disposed on substrate surface 102 over a channel region separating source region S₁₈₂ and drain region D₁₈₂. Referring to the perspective illustration at the top of FIG. 1, a width W21 of FG readout region 143 and a width W22 of FG readout region 144 are also set by the feature size of HV-PMOS and HV-NMOS devices formed by the standard semiconductor fabrication process utilized to fabricate sensor 100. For example, when sensor 100 is fabricated using a standard 0.18 μm CMOS process flow that includes forming “normal” HV-PMOS transistors with gate widths of 0.3 μm and “normal” HV-NMOS transistors with gate widths of 0.35 μm, FG structure is patterned such that FG readout region 143 has a width W21 of 0.35 μm, and such that FG readout region 144 has a width W22 of 0.3 μm. By forming the readout transistors of readout circuit 180 using a nano-scale (e.g., 0.18 μm CMOS) fabrication process such that the device sizes and oxide thicknesses are minimized, the influence of radiation on the readout process is minimized.

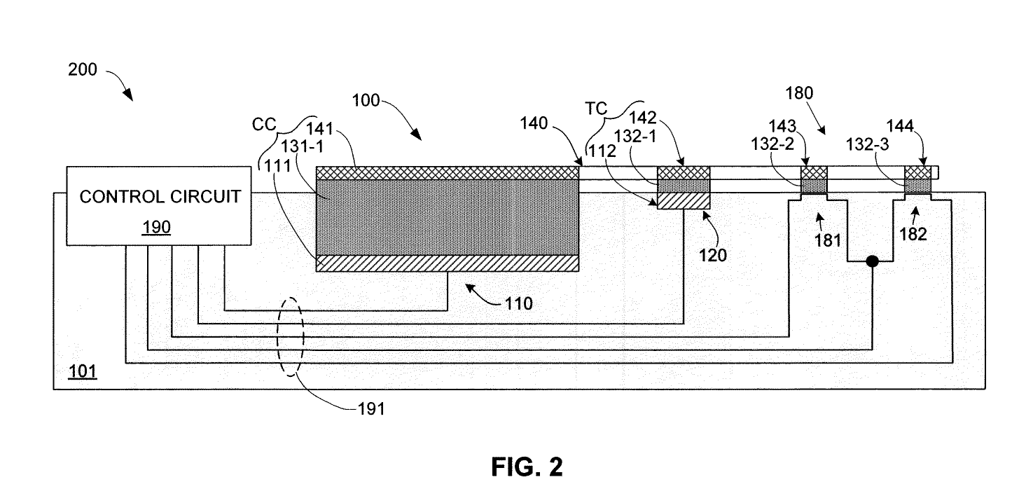

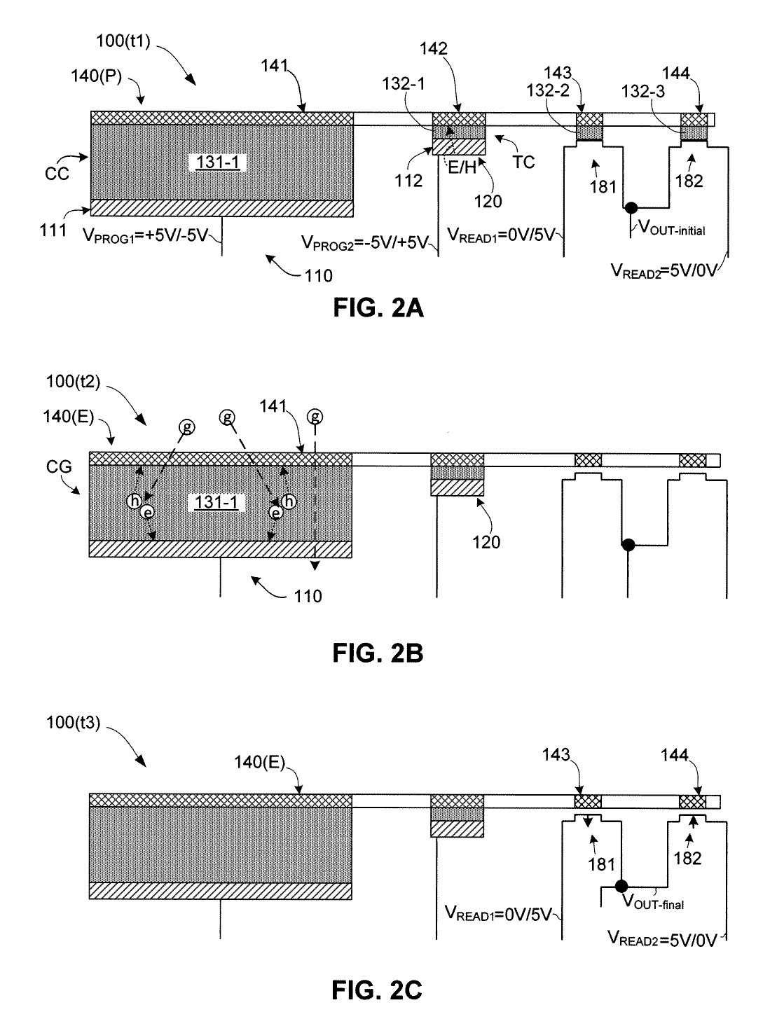

FIG. 2 is a simplified representation showing solid state direct radiation sensing device 200, and in particular showing both sensor 100 and a control circuit 190 that are simultaneously fabricated on substrate 101 (e.g., using the same standard CMOS fabrication flow that is used to produce the sensor 100). Note that FIG. 2 introduces simplified structural representations that are used below to better describe the novel aspects of sensor 100. Specifically, referring to control capacitor CC, P-well region 111 is indicated by single-diagonal cross-hatching, dielectric structure 131-1 is indicated by the large shaded region, and control capacitor region 141 of FG structure 140 is indicated by the double-diagonal cross-hatched region above dielectric structure 131-1. Similarly, P-well region 112 of tunneling capacitor TC is indicated by single-diagonal cross-hatching, gate oxide portion 132-1 is indicated by the small shaded region, and tunneling capacitor region 142 of FG structure 140 is indicated by the double-diagonal cross-hatched region above gate oxide 132-1. Readout transistors 181 and 182 are similarly depicted by gate oxide regions 132-2 and 132-3 and readout regions 143 and 144 of FG structure 140. Control circuit 190 applies various programming and bias voltage signals on control gate 110, tunneling gate 120 and readout transistors 181 and 182 of readout circuit 180 by way of signal lines 191, for example, according to the exemplary operating scheme such forth below, and processes signals read from readout circuit 180. Note that the simplified diagram indicates that signal lines 191 are disposed in substrate 101, but in reality these lines are formed by metallization disposed over sensor 100 and connected as indicated in FIG. 1.

An exemplary operating scheme is now described with reference to FIGS. 2A to 2C, which are simplified versions of FIG. 2.

FIG. 2A shows sensor 100 during a pre-exposure programming (charging) period (which is indicated in the figure as “100(t1)”) in which an initial charge is stored on FG structure 140 (which is indicated in the figure as “140(P)”). To generate the initial charge by Fowler-Nordheim tunneling, control circuit 190 simultaneously applies opposite programming voltages (e.g., V_{PROG1}=+5V and V_{PROG2}=5V, or V_{PROG1}=−5V and V_{PROG2}=+5V) on control gate 110 (i.e., on isolated P-well region 111) and tunneling gate 120 (i.e., isolated P-well region 112) of each sensor 100. Because of the large capacitive difference between control capacitor CC and tunneling capacitor TC (e.g., 10 to 20 times), these opposite voltages cause most of 10V potential to fall on tunneling capacitor TC, thereby causing Fowler-Nordheim tunneling of electrons or holes (“E/H”), depending on the polarity of applied voltages, from isolated P-well region 112 through gate oxide portion 132-1 to tunneling capacitor region 142 of FG structure 140. For example, to pre-charge FG structure 140 by electrons (i.e., to store a net-negative charge on FG structure 140), control circuit generates V_{PROG1} as +5V and V_{PROG2} as −5V. Conversely, to pre-charge FG structure 140 by holes (i.e., to store a net-positive charge on FG structure 140), control circuit generates V_{PROG1} as −5V and V_{PROG2} as +5V. This approach divides the total applied 10V potential between the two gates (nodes), and further enhances production by standard CMOS processing because the required voltages (i.e., −5V and +5V) are typically available on standard CMOS devices. It is also possible to perform sensor charging, for example, by applying +10V to P-well 111 and 0V to P-well 112, but this option is less preferable because it could lead to higher power consumption and require special high-voltage devices. The E/H charge injected through tunneling capacitor TC spreads over FG structure 140 (i.e., because FG structure 140 is conductive, all regions of FG structure 140 are at the same potential). Accordingly, the initial charge generates initial current rates through readout transistors 181 and 182 (by way of readout regions 143 and 144, respectively), which are read by applying suitable read voltages (e.g., V_{READ1}=0V and V_{READ2}=1.8V), measuring the resulting readout transistor output voltage values V_{OUT-initial}, and recording these values for later comparison.

FIG. 2B shows sensor 100 during a subsequent exposure period (which is indicated in the figure as “100(t2)”) during which sensor 100 is subjected to ionizing Gamma photon radiation “g”, which is absorbed everywhere inside the chip on which sensor 100 is fabricated. After gamma photon interaction with the silicon substrate, electron-hole pairs (E/H) are created that either recombine or remain separated. The separation of electron-hole pairs is enhanced in the areas where the electrical field exists, i.e., inside dielectric structure 131-1 under FG structure 140. As indicated, the separated (electron or hole) charges “migrate” to FG structure 140 and to control gate 110. Depending on the stored (i.e. positive or negative) charge, either the electrons “e” or holes “h” are drawn to control capacitor region 141 of FG structure 140, thereby discharging the stored charge (electron-hole pairs and their separation is shown in FIG. 2B). Because the control gate dielectric (i.e., STI dielectric structure 131-1) is much thicker than the tunneling gate dielectric, discharging of FG structure 140 is dominated by the electron-hole pairs generated in the control gate capacitor CG. Electron-hole pairs generated in other areas of the chip (where there is no electric field) recombine and typically do not influence the sensor. In the present embodiment, control circuit 190 remains inactive during the exposure period (i.e., no biasing voltages are applied to control gate 110 or tunneling gate 120 during the exposure period). The amount of charge removed from FG structure 140 is proportional to an amount of received ionizing radiation (i.e., due to electron/hole separation in STI dielectric structure 131-1).

FIG. 2C shows sensor 100 during a subsequent readout period (which is indicated in the figure as “100(t3)”) during which sensor 100 is operated to determine the potential of the floating gate 140 after irradiation. In the exemplary embodiment, control circuit 190 measures the potential of FG structure 140 by measuring “final” currents passed through readout transistors 181 and 182. Because the potential is the same in all regions of FG structure 140, it can be read by applying suitable read voltages (e.g., V_{READ1}=0V and V_{READ2}=1.8V) to readout transistors 181 and 182, measuring the resulting readout voltage value V_{OUT-final}, and then comparing the value V_{OUT-final} with the initial values V_{OUT-initial} that were read at the end of the charging period.

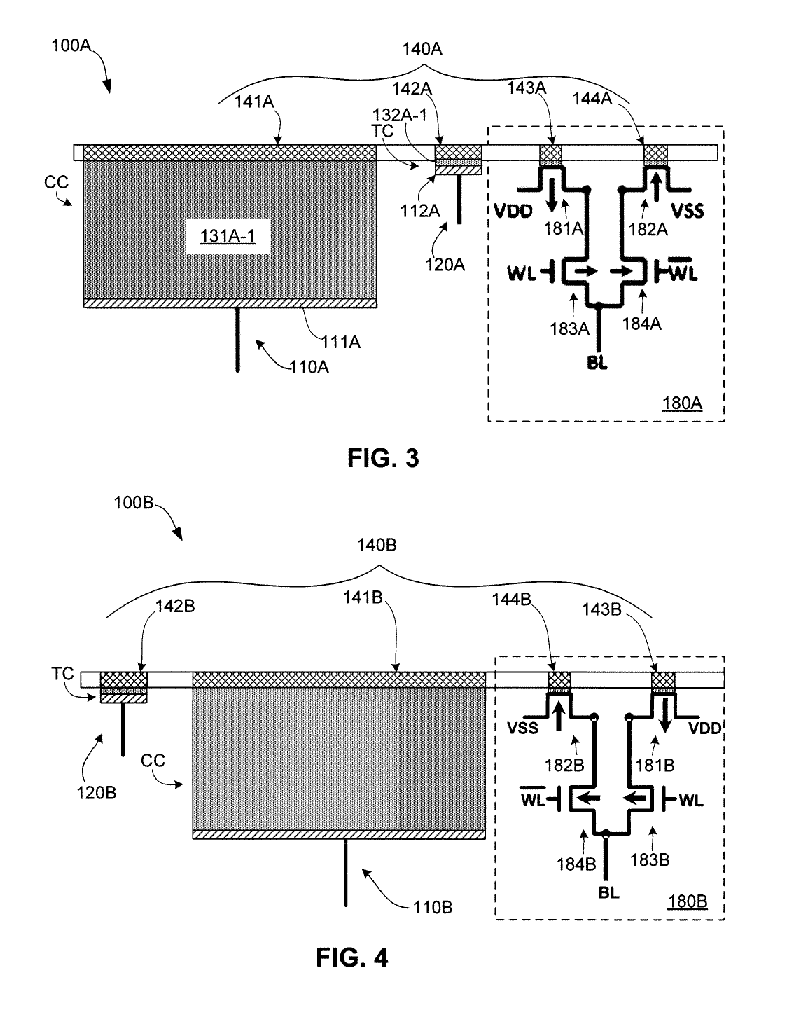

FIG. 3 shows a simplified sensor 100A according to a modified embodiment in which readout circuit 180A is implemented using a CMOS inverter. Similar to the embodiment set forth above, sensor 100A includes a FG structure 140A having a large control capacitor region 141A that forms a control capacitor CC with a control gate 110A (isolated P-well region 111A) and thick dielectric structure 131A-1, and a smaller tunneling capacitor region 142A that forms a tunneling capacitor TC with a tunneling gate 120A (isolated P-well region 112A) and a thin gate oxide portion 132A-1, where these structures are formed and operate in the manner described above. Referring to the right side of FIG. 3, similar to the previous embodiment, readout circuit 180A also includes a PMOS transistor 181A having source and drain terminals formed in a N-well region (not shown) and a gate structure formed by (third) readout region 143A of FG structure 140, and an NMOS transistor 182A including source and drain terminals formed in an P-well region (not shown) and having a gate structure formed by (fourth) readout region 144A of FG structure 140. To implement the CMOS inverter circuit, readout circuit 180A further includes a “standard” PMOS transfer transistor 183A and a “standard” NMOS transistor 184A that are respectively connected between readout transistors 181A and 182A and a bitline BL, with the gate terminals of transfer transistors 183A and 184A respectively connected to word lines WL and WL-bar. During a read operation, system voltages VDD and VSS are respectively supplied by the control circuit (not shown) to the source terminals of readout transistors 181A and 182A, and the residual (post-exposure) charge stored on FG structure 140 is estimated by measuring a shift in the voltage transfer curve of the CMOS inverter circuit caused by exposure to radiation using known techniques.

FIG. 4 shows a simplified sensor 100B according to another modified embodiment in which the gates and circuits of sensor 100A are “reversed” to show that the control capacitor CC, tunneling capacitor TC and CMOS inverter 180B may be arranged in essentially any order, provided they share the same FG structure 140B. In particular, FG structure 140B is patterned such that control capacitor region 141B is disposed between tunneling capacitor region 142B and readout circuit 180B, and such that readout region 144B (associated with NMOS readout transistor 182B) is disposed between control capacitor region 141B and readout region 143B (associated with PMOS readout transistor 181B), with the positions of transfer transistors 183B and 184B also reversed.

Various additional alternative embodiments are presented below that include additional features are optionally employed to achieve improved sensor performance.

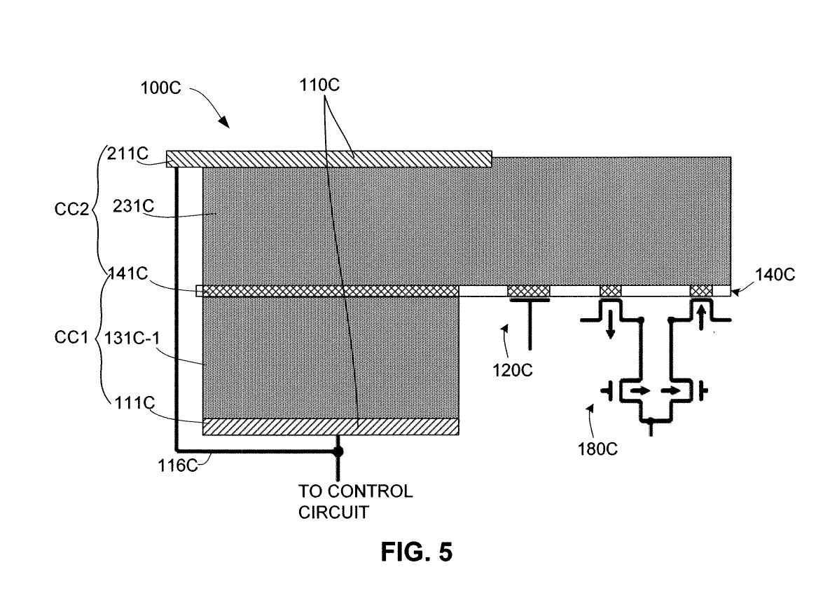

FIG. 5 is a simplified diagram showing a first alternative embodiment in which each sensor 100C of a sensor device includes a two-part control gate 110C. Similar to the previous embodiments, sensor 100C includes a FG structure 140C, an isolated P-well region 111A and intervening STI dielectric structure 131C-1, and in addition includes a tunneling gate 120C and a readout circuit 180C, all of which are formed and function essentially as described above. Sensor 100C differs from the previous embodiments in that an additional (second) dielectric layer 231C is formed over FG structure 140C, and a patterned metal plate 2110 is disposed on dielectric layer 231C and positioned over the control capacitor region 141C of FG structure 1400, wherein both dielectric layer 231C and metal plate 211C are formed using existing standard CMOS processes and according to known techniques. Patterned metal plate 211C and isolated P-well 111C are electrically connected, for example, by way of standard metallization structure 116C and associated contact structures, to form two-part control gate 1100. This arrangement also forms two substantially equal control capacitors including “lower” capacitor CC1 (i.e., formed by isolated P-well 111C, STI dielectric structure 131C-1 and FG control capacitor region 141C) and an upper (second) capacitor CC2 formed by patterned metal plate 211C, additional dielectric layer 231C and FG control capacitor region 141C. Because capacitors CC1 and CC2 are connected in parallel, the same control capacitance can be achieved using a half of the 141C region footprint. Additional dielectric layer 231C provides a second thick sensing volume that increases electron-hole generation and discharge of FG unit area during exposure. Accordingly, two-part control gate 110C facilitates the production of sensor devices in which each sensor 100C has a reduced size (e.g., approximately 50% smaller than the single control gate embodiment described above) without decreasing total sensor control capacitance.

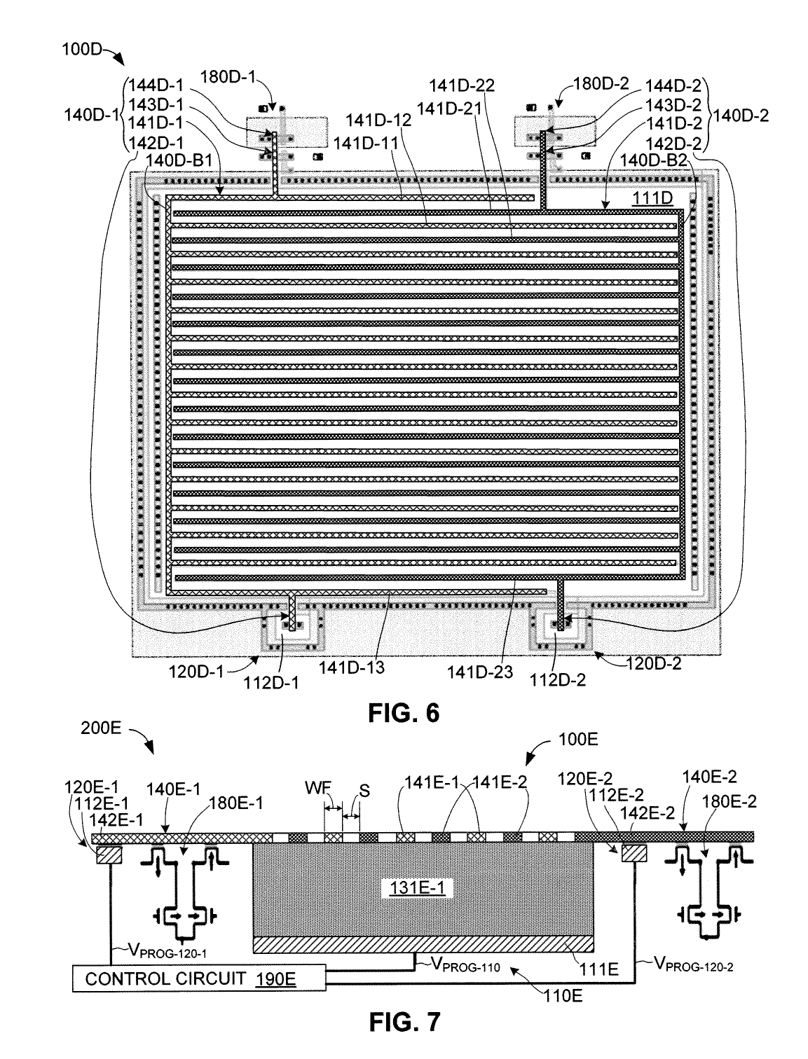

FIG. 6 is a top view showing a sensor 100D according to a second alternative embodiment in which two comb-shaped coupled FG structures 140D-1 and 140D-2 are utilized to enhance sensitivity to radiation. FG structures 140D-1 and 140D-2 are separate polycrystalline silicon structures that are formed on an STI dielectric structure (not shown) over an isolated P-well region 111D. FG structure 140D-1 includes a comb-like control capacitor region 141D-1 including multiple parallel (horizontal) fingers (e.g., fingers 141D-11 and 141D-12) extending rightward from a (vertical) base portion 141D-B1. FG structure 140D-1 also includes a tunnel capacitor region 142D-1 extending downward from a lowermost finger 143D-13 to form an associated (first) tunneling gate 120D-1, and readout regions 143D-1 and 144D-2 disposed on a (vertical) structure extending upward from uppermost finger 141D-11 into readout circuit 180D-1. Similarly, FG structure 140D-2 includes comb-like control capacitor region 141D-2 including multiple parallel (horizontal) fingers (e.g., fingers 141D-21 and 141D-22) extending leftward from a (vertical) base portion 141D-B1, a tunnel capacitor region 142D-2 extending downward from a lowermost finger 143D-23 into a tunneling gate 120D-2, and readout regions 143D-2 and 144D-2 extending upward from uppermost finger 141D-21 into a readout circuit 180D-2.

According to a first aspect of sensor 100D, FG structures 140D-1 and 140D-2 are patterned such that the parallel (horizontal) fingers of comb-like control capacitor region 141D-1 are interdigitated with the parallel (horizontal) fingers of comb-like control capacitor region 141D-2. For example, finger 141D-12 of control capacitor region 141D-1 extends between fingers 141D-21 and 141D-22 of control capacitor region 141D-2, and finger 141D-21 of control capacitor region 141D-2 extends between fingers 141D-11 and 141D-12 of control capacitor region 141D-1. As set forth below, this arrangement facilitates the generation of an enhanced electric field that produces a higher recombination yield (i.e., more electrons/holes reach FG structures 140D-1 and 140D-2 to cause discharge during exposure).

According to another aspect, sensor 100D includes two separate tunneling gates 120D-1 and 120D-2 respectively connected to FG structures 140D-1 and 140D-2. Tunneling gate 120D-1 is formed by tunneling capacitor region 142D-1 of FG structure 140D-1, which is disposed over a (second) isolated P-well region 112D-1 in the manner described above. Similarly, tunneling gate 120D-2 is formed by tunneling capacitor region 142D-2 and a (third) isolated P-well region 112D-2. As described below with reference to FIG. 7, separate tunneling gates 120D-1 and 120D-2 are provided to facilitate programming each FG structure 140D-1 and 140D-2 to opposite potentials (charging with electrons or holes).

FIG. 7 is a simplified diagram showing a sensor device 200E including a sensor 100E and a control circuit 190E fabricated on a single substrate in the manner described above. Sensor 100E is similar to sensor 100D (FIG. 6) in that two FG structures 140E-1 and 140E-2 include respective control capacitor regions 141E-1 and 141E-2 having interdigitated fingers (shown in end view) disposed over a STI dielectric structure 131E-1, respective tunneling capacitor regions 142E-1 and 142E-2 forming tunneling gates 120E-1 and 120E-2 over associated P-well regions 112E-1 and 112E-2, and respective readout regions 143E-1/144E-1 and 143E-2/144E-2 forming respective readout transistors of CMOS inverter readout circuits 180E-1 and 180E-2. Note that (like sensor 100D), sensor 100E utilizes a single control gate 110E formed by isolated P-well region 111E to control both FG structures 140E-1 and 140E-2. Sensor 100E differs from sensor 100D only in that tunneling gates 120E-1 and 120E-2 and readout circuits 180E-1 and 180E-2 are repositioned for illustrative purposes.

According to another aspect of the present embodiment, control circuit 190E is configured using known techniques to apply different (first and second) programming voltages V_{PROG-120-1} and V_{PROG-120-2} on tunneling gates 120E-1 and 120E-2 during pre-exposure programming operations in order to store opposite (i.e., net-positive and net-negative) initial charges on FG structures 140E-1 and 140E-2. In one specific embodiment, during a first phase of the pre-exposure programming period, a positive voltage (e.g., +5V) is applied both to control gate 110E and to tunneling gate 120E-2, and a negative voltage (e.g., −5V) is applied to tunneling gate 120E-1, thereby generating Fowler-Nordheim tunneling of electrons that produces a net-negative charge on FG structure 140E-1. During a second phase of the pre-exposure programming period, a negative voltage (e.g., −5V) is applied to control gate 110E and to tunneling gate 120E-1, and a positive voltage (e.g., +5V) is applied to tunneling gate 120E-2, whereby Fowler-Nordheim tunneling of holes generates a net-positive charge on FG structure 140E-2. Of course, the above process can be reversed to store a net-positive charge on FG structure 140E-1 and a net-negative charge on FG structure 140E-2. Pre-charging FG structures 140E-1 and 140E-2 in this manner produces an enhanced electric field separating the different (net-positive and net-negative) charges during ionization, which in turn leads to decreased recombination (i.e., more electrons/holes reach FG structures 140E-1 and 140E-2 to discharge the respective initial net-negative and net-positive charges). During post-exposure readout, control circuit 190E operates in a manner similar to that described above to estimate a received radiation dose by determining changes in the Vin-Vout curve of both CMOS inverter readout circuits 180E-1 and 180E-2.

All of the sensor embodiments presented above are characterized by passive exposure operations (i.e., none of the sensors consume electric power during exposure to radiation, and power is only consumed during the programming/charging and read-out processes). Although this passive exposure characteristic provides an ultra-low-power operating scheme that is highly desirable for certain mobile applications because it minimizes power consumption, it may produce undesirably low radiation detection (i.e., low sensor sensitivity) in the sensor structures described above with reference to FIGS. 1-7 due to high electron/hole recombination in the thick dielectric forming the control capacitors. Conversely, while applying a biasing voltage to the FG structure during exposure (i.e., by way of the control gate) can increase the resulting electric field in the STI dielectric, which would suppress electron/hole recombination. Nevertheless, such an approach may produce undesirable charge loss from the FG structure due to leakage through the thin tunneling dielectric (gate oxide) forming the tunneling capacitor.

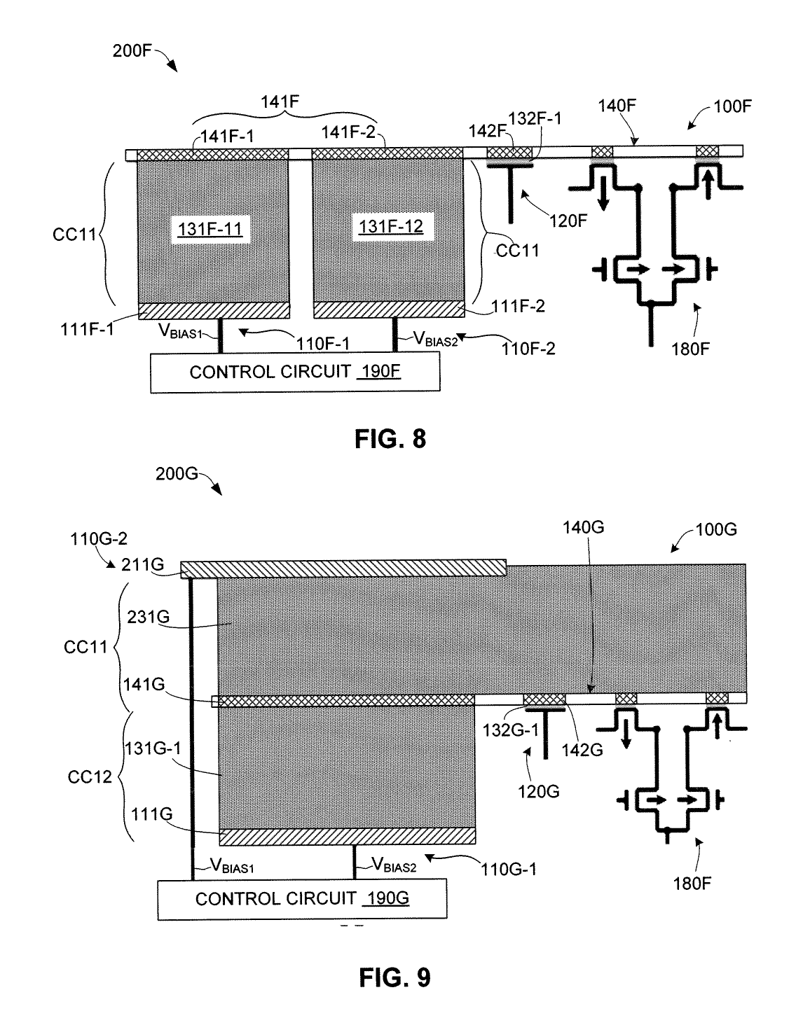

According to the embodiments described below with reference to FIGS. 8 and 9, sensors are provided that include two control gates (and two substantially identical control capacitor portions) that apply opposite biasing voltages (e.g., +5V and −5V) on the FG structure during the exposure period. By separating the control capacitor into two identical capacitor portions, and by applying opposite (positive/negative) biasing voltages to the two control gates, the desired enhanced electric field is generated in the thick dielectric by one of the two capacitor portions (e.g., the control capacitor portion biased with +5V and FG precharged with electrons) to increase sensor sensitivity, while tunneling through the thin gate oxide is suppressed by the other capacitor portion (e.g., the control capacitor portion biased with −5V and FG precharged with electrons), thereby avoiding undesirable charge loss. As such, in both of the embodiments described below with reference to FIGS. 8 and 9, the potential of the FG structure is not influenced by the applied bias voltage. Because the electron-hole recombination strongly (super linear) depends on the field in the dielectric, the net effect of applying opposing electric fields results in a net decrease in the recombination of electron-hole pairs in the dielectrics of the control gate during exposure, which results in enhanced sensor performance.

FIG. 8 is a simplified cross-sectional view showing a portion of a sensor device 200F including a sensor 100F and a control circuit 190F. Sensor 100F is similar to previous embodiments in that it includes a tunneling gate 120F and a readout circuit 180F that are formed and operate in the manner described above. Sensor 100F differs from previous embodiments in that it includes two control gate portions: a first control gate 110E-1 implemented by isolated P-well region 111F-1 in the manner described above, and a second control gate 110E-2 implemented by a (third) isolated P-well region 111F-2 formed in substrate 101 adjacent to P-well region 111F-1. In addition, sensor 100F differs from previous embodiments in that FG structure 140F includes a two-part control capacitor region 141F including a first control capacitor region portion 141F-1 that is formed over a first STI structure 131F-11 and capacitively coupled to first control gate 110E-1, and a second control capacitor region portion 141F-2 that is formed over a second STI structure 131F-12 and capacitively coupled to second control gate 110E-2. This arrangement provides two substantially equal control capacitors: control capacitor CC11 formed by control gate 110E-1 (i.e., isolated P-well region 111F-1), STI dielectric portion 131F-11 and control capacitor region portion 141F-1, and control capacitor CC12 formed by second control gate 110E-2 (i.e., isolated P-well region 111F-2), STI dielectric portion 131F-12 and control capacitor region portion 141F-2. In addition, sensor device 200F differs from previous embodiments in that control circuit 190F is modified to simultaneously apply opposite biasing voltages (e.g., V_{BIAS1}=+5V and V_{BIAS2}=−5V, or V_{BIAS1}=−5V and V_{BIAS2}=+5V) on control gates 110E-1 and 110E-2 during the exposure period, thereby generating the beneficial effect described above.

FIG. 9 is a simplified cross-sectional view showing a portion of a sensor device 200G including a sensor 100G and a control circuit 190G. Sensor 100G is similar to previous embodiments in that it includes a tunneling gate 120G and a readout circuit 180G that are formed and operate in the manner described above. Sensor 100G differs from previous embodiments in that it includes two control gate portions: a first control gate 110G-1 implemented by isolated P-well region 111G-1 in the manner described above, and a second control gate 110G-2 implemented by a metal plate 211G formed on the dielectric layer 231G that is deposited over FG structure 140G in a manner similar to that described above with reference to FIG. 5. This arrangement also provides two substantially identical control capacitors: control capacitor CC11 formed by control gate 110G-1 (i.e., isolated P-well region 111G-1), STI dielectric portion 131G-1 and control capacitor region portion 141G-1, and control capacitor CC12 formed by second control gate 110G-2 (i.e., metal plate 211G), dielectric layer 231G and control capacitor region portion 141G. Similar to device 200F (described above), sensor device 200G includes a control circuit 190G that is modified to simultaneously apply opposite biasing voltages (e.g., V_{BIAS1}=+5V and V_{BIAS2}=−5V, or V_{BIAS1}=−5V and V_{BIAS2}=+5V) on control gates 110G-1 and 110G-2 during the exposure period, thereby generating the beneficial effect described above.

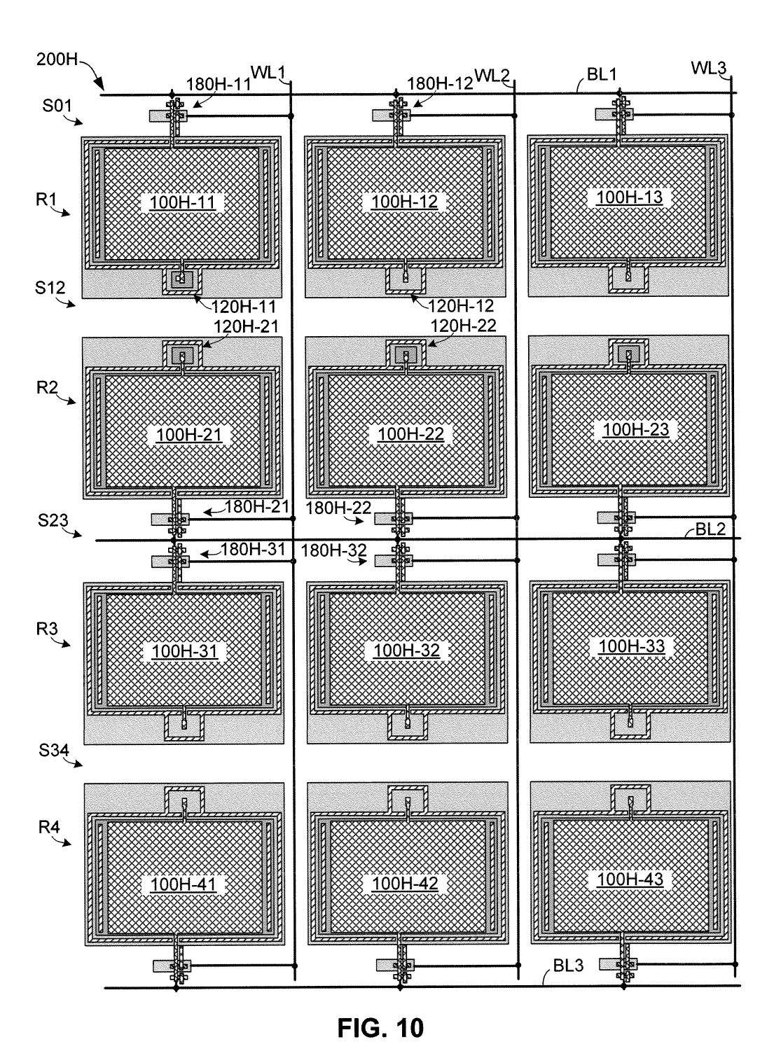

FIG. 10 is a top plan view showing a radiation sensing device 200H according to a simplified exemplary practical embodiment including an array of sensors 100H disposed in parallel rows R1 to R4 such that each adjacent pair of rows is separated by an associated horizontal space S12 to S34, and such that the readout circuits of the sensors in each row are connected to at least one horizontal bitline BL1 to BL3 and at least one vertical wordline WL1 to WL3 (the control and tunneling gates have their own routing, not shown). For example, row R1 (including sensors 100H-11 to 100H-13) and row R2 (including sensors 100H-21 to 100H-23) are separated by horizontal space S12. Readout circuits 180H-11 and 180H-12 of the sensors 100H-11 and 100H-12 in row R1 are collectively connected to bitline BL1 and separately connected to wordlines WL1 and WL2, respectively. Similarly, readout circuits 180H-21 and 180H-22 of sensors 100H-21 and 100H-22 in row R2 are collectively connected to bitline BL2 and separately connected to wordlines WL1 and WL2, respectively. Row R2 is separated from row R3 (sensors 100H-31 to 100H-33) by space S23, and R3 is separated from row R4 (sensors 100H-41 to 100H-43) by space S34, and the readout circuits of each sensor are connected to associated bitlines. It is noted that the simplified representation omits for illustrative purposes additional wordlines and bitlines that would typically be needed to operate sensor device 200H.

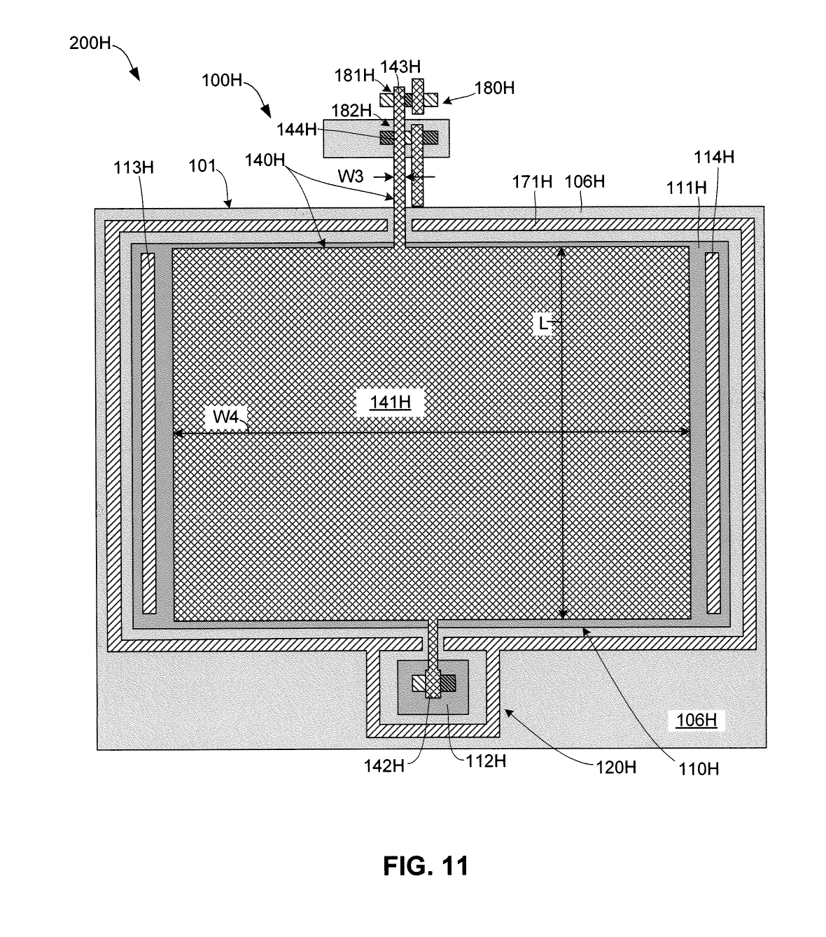

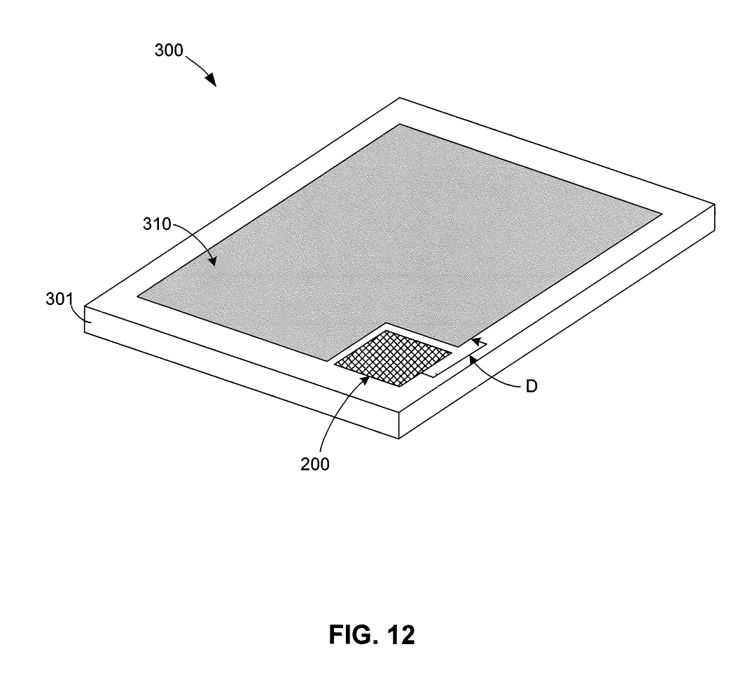

FIG. 11 is an enlarged top view showing a single sensor 100H of the array shown in FIG. 10. Sensor 100H includes a control gate 110H, a tunneling gate 120H, an FG structure 140H, and a readout circuit 180H that are formed in a manner similar to that described above. Control gate 110H and tunneling gate 120H are formed in isolated P-well regions 111H and 112H, respectively, which are surrounded by an N-well region 106H. FG structure 140H includes a tunneling capacitor region 142H extending from a lower end of a centrally located control capacitor region 141H, and readout regions 143H and 144H disposed on a polysilicon finger extending from an upper end of control capacitor region 141H. Control gate 110H is operated by way of elongated contact structures 113H and 114H that extend along the side edges of control capacitor region 141H, and contact P-well region 111H in the manner similar to that described above with reference to FIG. 1. Readout circuit 180H is disposed outside of N-well region 106H, which is biased by way of peripheral contact structure 171H in the manner similar to that described above.

According to the exemplary practical embodiment, sensor 100H is fabricated using a single-poly nano-scale (e.g., 0.18 μm) CMOS fabrication process in which FG structure is sized such that a width W3 of FG readout gate regions 143H and 144H is approximately 0.3 μm to 0.35 μm, and FG control capacitor region 141H has a width W4 and a length L equal to approximately 20 μm. Sensitivity of CMOS devices to ionizing radiation (total ionization dose-TID) strongly decreases in nano-scaled CMOS, so nano-scale (e.g., sub-micron) CMOS devices are less sensitive to ionizing radiation than larger CMOS devices. However, in other embodiments, sensors can be constructed in accordance with the present invention using other technologies such that the FG structure includes readout region widths in the range of 22 nm and 1 μm, and control capacitor regions having length and width dimensions in the range of 1 μm to 1000 μm. Forming the various sensors of the present invention with readout circuits 180H having thin gate oxide with thicknesses below 15 nm provides radiation sensors with reduced risk of malfunction due to ionizing radiation. At the same time, utilization of FG discharging principles enables creation of high sensitivity radiation silicon sensors, so constructing the various sensors of the present invention with FG control capacitor regions 141H with a width W4 and length L comparable to the exemplary embodiment. Combining these two concepts (i.e., floating gate-based radiation sensors with small CMOS readout transistors and large control capacitors with thick oxide) produces a unique combination of analog electronic designs that include sensors and radiation hard control (detecting/processing) circuitry on the same silicon substrate. Moreover, because the sensors are small and ultra-low power consuming (i.e., below 1 μW), sensor devices formed in accordance with the present invention are suitable for a variety of challenging applications, in particular, in systems employing radiation for sterilization, radiation safety and security devices, in-vivo dosimeters for precise dose delivery control in radiation therapy and other medical devices. As illustrated in FIG. 12, application of embedded radiation sensors also facilitates the production of CMOS circuits 300 with enhanced radiation hardness that include both “functional” CMOS circuitry 310 and a radiation sensing device 200 on a single silicon “chip” 301. Radiation sensing device 200 is constructed in accordance with any of the embodiments described above, with the control circuit modified according to known techniques to generate received dosage data D (i.e., using information received from the sensor array), and to transmit dosage data D to functional circuit 310. Functional circuitry 310 includes a processor or application specific circuitry that is configured to perform a predefined function (e.g., aircraft guidance), and is modified using known techniques to receive and process dosage data D such that functional circuit 310 automatically corrects circuit operating parameters (e.g., corrections of the electronic circuit sensitivity, voltage offsets, etc.) to account for an absorbed dose indicated by dosage data D.

Referring again to FIG. 10, according to another embodiment, sensors 100H-11 to 100H-43 are arranged in an alternating (flipped) pattern such that the tunneling gates and readout circuits of adjacent rows are disposed in corresponding horizontal spaces and connected to shared shared bitlines. For example, sensors 100H-21 to 100H-23 of row R2 and sensors 100H-11 to 100H-13 of row R1 are “flipped” relative to each other such that tunneling gates 120H-11 and 120H-21 of sensors 100H-11 and 100H-21 are disposed in the same vertical space S12 (i.e., a space that corresponds to merging of n-well and isolated p-well regions). Similarly, the sensors of row R2 are “flipped” relative to those of row R3 such that readout circuits 180H-21 and 180H-31 of sensors 100H-21 and 100H-31 are disposed in the same horizontal space (i.e., space S23), and sensing device 200H includes a (second) bitline structure BL2 extending along space S23 and operably connected to readout circuitry of each sensor 100H-21 to 100H-23 and each sensor 100H-31 to 100H-33 in (second and third) rows R2 and R3. This arrangement enables random access for pre-charging and reading (e.g., by way of bitlines BL1 to BL3 and wordlines WL1 to WL3 disposed along the spaces between associated rows and columns of sensors) and significant reduction of the total array footprint. This feature is useful because the sensors described herein can be used several times (i.e., the sensors are not disposable in that, after irradiation, the sensors can be charged/reprogrammed and used again). Further, because the sensitivity of the sensors depends on the level of charging, this feature is useful in that it facilitates periodical additional charging that sustains high sensitivity and improves linearity to the absorbed dose.

Although the present invention has been described with respect to certain specific embodiments, it will be clear to those skilled in the art that the inventive features of the present invention are applicable to other embodiments as well, all of which are intended to fall within the scope of the present invention.

1. A solid state direct radiation sensing device including a plurality of sensors formed on a semiconductor substrate, wherein each sensor comprises:
at least one control gate including a first isolated P-well region formed in the substrate;
a dielectric portion formed on said substrate and disposed over the first isolated P-well region; and
a first floating gate structure including a control capacitor region disposed on the dielectric portion and over the first isolated P-well region.

2. The sensor device of claim 1, wherein each said sensor further comprises:
at least one tunneling gate including a second isolated P-well region formed in the substrate and separated from said first isolated P-well region by an N-well region; and
a gate oxide layer including a tunneling gate oxide portion disposed over the second isolated P-well region,
wherein the first floating gate structure further includes a tunneling capacitor region disposed on the tunneling gate oxide portion and over the second isolated P-well region, and
wherein a first thickness of the dielectric layer is at least five times greater than a second thickness of said gate oxide layer.

3. The sensor device of claim 2,
wherein the first isolated P-well region, the dielectric portion and the control capacitor region of the first floating gate structure form a first capacitor having a first capacitance,
wherein the second isolated P-well region, the tunneling gate oxide portion and the tunneling capacitor region of the first floating gate structure form a second capacitor having a second capacitance, and
wherein the first capacitance is at least five times greater than the second capacitance.

4. The sensor device of claim 2,
wherein the first floating gate structure of each said sensor further includes at least one readout region, and
wherein said each sensor further comprises at least one readout transistor having source and drain regions disposed in the substrate under said at least one readout region.

5. The sensor device according to claim 4, wherein said readout circuit of each said sensor comprises a CMOS inverter including a PMOS transistor having source and drain terminals formed in an N-well region of said substrate and having a gate structure formed by a third region of said first floating gate structure, and an NMOS transistor including source and drain terminals formed in a P-well region of said substrate and having a gate structure formed by a fourth region of said first floating gate structure.

6. The sensor device of claim 4, further comprising a control circuit fabricated on the substrate, said control circuit including:
means for applying opposite programming voltages on the control gate and the tunneling gate of each said sensor during a pre-exposure period such that Fowler-Nordheim tunneling occurs between the second isolated P-well region and the first floating gate structure, whereby an initial charge is stored on the first floating gate structure of each said sensor; and
means for reading a residual charge stored on the first floating gate structure of each said sensor after said pre-exposure period, whereby an amount of radiation absorbed by said each sensor is determined by a difference between the first and second charge amounts.

7. The sensor device of claim 1, wherein each said sensor further comprises a second dielectric layer disposed over the first floating gate structure, wherein the control gate further comprises a metal plate disposed on the second dielectric layer and positioned over the control capacitor region of the first floating gate structure, wherein the metal plate of said each sensor is electrically connected to the first isolated P-well region of said each sensor.

8. The sensor device of claim 7,
wherein the first isolated P-well region, the dielectric portion and the control capacitor region of the first floating gate structure form a first control capacitor having a first capacitance,
wherein the metal plate, the second dielectric layer and the control capacitor region of the first floating gate structure form a second control capacitor having a second capacitance that is substantially equal to the first capacitance of the first control capacitor.

9. The sensor device of claim 2,
wherein each said sensor further comprises a second floating gate structure including a second control capacitor region disposed on the dielectric portion and over the first isolated P-well region,
wherein the control capacitor region of the first floating gate structures and the second control capacitor region of the second floating gate structures comprise comb-like polycrystalline silicon structures having a plurality of parallel fingers, and
wherein the first and second floating gate structures are arranged such that the plurality of parallel fingers of the first floating gate structure are interdigitated with the plurality of parallel fingers of the second floating gate structure.

10. The sensor device of claim 9,
wherein said at least one tunneling gate of each said sensor comprises a first tunneling gate including said second isolated P-well region and a second tunneling gate including a third isolated P-well region formed in the substrate and separated from said first and second isolated P-well regions,
wherein the second floating gate structure of each said sensor further comprises a second tunneling capacitor region disposed over the third isolated P-well region, and
wherein the sensor device further comprises means for applying a first programming voltage on the control gate, a second programming voltage on the first tunneling gate and third programming voltage on the second tunneling gate of each said sensor during a pre-exposure period such that Fowler-Nordheim tunneling of holes occurs between the substrate and the first floating gate structure and Fowler-Nordheim tunneling of electrons occurs between the substrate and the second floating gate structure, whereby an initial net-positive charge is stored on the first floating gate structure and initial net-negative charge is stored on the second floating gate structure.

11. The sensor device of claim 1,
wherein said at least one control gate of each said sensor comprises a first control gate including said first isolated P-well region and a second control gate,
wherein both of said first and second control gate of said each sensor are capacitively coupled to said floating gate structure of said each sensor, and
wherein the sensor device further comprises means for respectively applying opposite biasing voltages on the first control gate and the second control gate during an exposure period.

12. The sensor device of claim 11,
wherein the control capacitor region of each said floating gate structure includes a first control capacitor region portion that is capacitively coupled to said first control gate, and a second control capacitor region portion, and
wherein said second control gate of each said sensor includes a third isolated P-well region formed in the substrate below the second control capacitor region portion of said each floating gate structure.

13. The sensor device of claim 11, wherein each said sensor further comprises a second dielectric layer disposed over the first floating gate structure, wherein the second control gate of each said sensor comprises a metal plate disposed on the second dielectric layer and positioned over the control capacitor region of the first floating gate structure of said each sensor.

14. The sensor device of claim 4,
wherein said plurality of sensors disposed in a plurality of parallel rows such that first and second rows of said plurality of rows are separated by a first space, and
wherein said sensor device further comprises a first bitline structure operably connected to each said sensor in at least one of said first and second rows.

15. The sensor device of claim 14,
wherein the control capacitor region of said each sensor is disposed between said least one readout transistor and said at least one tunneling gate,
wherein said plurality of sensors are arranged in an alternating pattern such that the tunneling gates of each said sensor in said first and second rows are disposed in said first space disposed between said first and second rows, and such that said readout transistors of each said sensor in said second row are disposed in a second space between said second row and a third row of said plurality of parallel rows, and
wherein said sensor device further comprises a second bitline structure extending along said second space and operably connected to the readout circuitry of each said sensor in said second and third rows.

16. The sensor device of claim 5,
wherein the third and fourth readout regions of the floating gate of each said sensor has a width in the range of 22 nanometers (nm) and 1 micron (μm), and
wherein the FG control capacitor region has a width in a range of 1 μm and 1000 μm and a length in the range of 1 μm and 1000 μm.

17. A solid state direct radiation sensor formed on a semiconductor substrate, the sensor comprising:
a control gate including a first isolated well region formed in the substrate;
a tunneling gate including a second isolated well region formed in the substrate;
a first dielectric portion disposed over the first isolated well region;
a second dielectric portion disposed over the second isolated well region; and
a floating gate structure including:
a first region disposed on the dielectric portion such that the first region forms a first capacitance with the control gate, and
a second region disposed on the second dielectric portion such that the second region forms a second capacitance with the tunneling gate,
wherein a thickness of the first dielectric portion is at least five times greater than a thickness of the second dielectric portion, and
wherein the first and second capacitances are set such that Fowler-Nordheim tunneling is facilitated during a charging period when a first voltage potential is supplied to the control gate and a second voltage potential is supplied to the tunneling gate, thereby storing a first charge amount on the floating gate structure.

18. The sensor according to claim 17, wherein the first and second isolated well regions comprise spaced-apart P-well regions entirely disposed over a first N-well region formed in the substrate, and respectively surrounded by second N-well regions extending from an upper surface of the substrate to the deep N-well region.

19. The sensor according to claim 17, further comprising a readout circuit including at least one transistor having a gate structure formed by a third region of said floating gate structure.

20. The sensor according to claim 19, wherein said readout circuit includes a CMOS inverter comprising:
a PMOS readout transistor having source and drain terminals formed in a N-well region of said substrate and having a gate structure formed by said third region of said first floating gate structure;
an NMOS readout transistor including source and drain terminals formed in an P-well region of said substrate and having a gate structure formed by a fourth region of said first floating gate structure;
a PMOS transfer gate connected between the PMOS readout transistor and an output node; and
an NMOS transfer gate connected between the NMOS readout transistor and the output node.

21. A solid state direct radiation sensor formed on a semiconductor substrate, the sensor comprising:
an N-well region formed in said substrate, said N-well region including a deep N-well portion entirely disposed inside said substrate and extending under an entirety of said N-well region, and at least one second N-well portion extending from the deep N-well portion to a surface of said substrate and disposed in a peripheral area of said N-well region;
a control gate including a first isolated P-well region entirely disposed in the N-well region;
a tunneling gate including a second isolated P-well region entirely disposed in the N-well region;
a dielectric portion disposed over the first isolated P-well region;
a gate oxide dielectric portion disposed on the substrate surface over the second isolated P-well region;
a readout circuit including at least one readout transistor having source and drain regions formed in the substrate and disposed outside of said N-well region; and
a floating gate structure including a first region disposed on the dielectric portion, a second region disposed on the gate oxide dielectric portion, and a third region extending over the source and drain regions of the at least one readout transistor.

22. The sensor according to claim 21, wherein said readout circuit includes a CMOS inverter comprising:
a PMOS readout transistor having source and drain terminals formed in a N-well region of said substrate and having a gate structure formed by said third region of said first floating gate structure;
an NMOS readout transistor including source and drain terminals formed in an P-well region of said substrate and having a gate structure formed by a fourth region of said first floating gate structure;
a PMOS transfer gate connected between the PMOS readout transistor and an output node; and
an NMOS transfer gate connected between the NMOS readout transistor and the output node.

23. A CMOS circuit including a functional circuit and a solid state direct radiation sensing device formed on a semiconductor substrate, wherein the sensing device includes a plurality of sensors for generating dosage data and means for transmitting the dosage data to the functional circuit, wherein the functional circuit includes means for automatically correcting circuit operating parameters in accordance with said transmitted dosage data, and wherein each sensor of said sensing device comprises:
at least one control gate including a first isolated P-well region formed in the substrate;
a dielectric portion formed on said substrate and disposed over the first isolated P-well region; and
a first floating gate structure including a control capacitor region disposed on the dielectric portion and over the first isolated P-well region.
